(19) United States
(12) Patent Application Publication
(10) Pub. No.: US 2012/0218724 A1
(43) Pub. Date: Aug. 30, 2012

(54) DISPLAY DEVICE

(75) Inventor: Shinji SHIMIZU, Chiba (JP)

(73) Assignee: Hitachi Displays, Ltd.

(21) Appl. No.: 13/401,875

(22) Filed: Feb. 22, 2012

(30) Foreign Application Priority Data
Feb. 24, 2011 (JP) 2011-038527

(51) Int. Cl. H05K 7/06; H05K 7/14

(52) U.S. Cl. 361/749; 361/807

(57) ABSTRACT

Provided is a display device including: a display panel; a frame which holds the display panel; and a cushion which is softer than the frame, wherein the frame includes: a first portion which overlaps the display panel; a second portion which extends from the first portion more outwardly than an outer edge of the display panel; and a projecting portion which is formed on the second portion in a raised manner and faces a side surface of the outer edge of the display panel, and the cushion has a hole, is mounted on the projecting portion by fitting the projecting portion in the hole, and faces the side surface of the outer edge of the display panel in an opposed manner.

### CROSS-REFERENCE TO RELATED APPLICATION

The present application claims priority from Japanese application JP2011-038527 filed on Feb. 24, 2011, the contents of which are hereby incorporated by reference into this application.

### BACKGROUND OF THE INVENTION

1. Field of the Invention

The present invention relates to a display device.

2. Description of the Related Art

In a liquid crystal display device, the structure for holding a liquid crystal display panel is configured such that the periphery of the liquid crystal display panel formed using glass or the like is surrounded by a mold frame formed using polycarbonate or the like. Accordingly, when external stress such as vibrations or an impact is applied to a module, an edge of the liquid crystal display panel is brought into contact with the mold frame so that the liquid crystal display panel receives stress. As a result, there exists a possibility of the occurrence of cracks in glass forming the liquid crystal display panel, the occurrence of display irregularities by the stress, chipping of the mold frame, the generation of dusts or the like by shaving.

Accordingly, there has been proposed a method where a tape having a cushion property (hereinafter referred to as cushion tape) or the like is arranged on a portion of the mold frame which is brought into contact with an edge of the liquid crystal display panel or the like.

In arranging the cushion tape on the mold frame, it is necessary to take into account the unevenness of the cushion tape attributed to an adhesion tolerance, difficulty in adhering the cushion tape to a small region, peeling-off of the cushion tape from the mold frame due to the degradation of the tape with time or the like. Accordingly, it is difficult to adopt the cushion tape arranging method. This is because although a certain amount of area is necessary for arranging the cushion tape by taking into account these factors, it is necessary for a high definition product to arrange a large number of drive films for driving liquid crystal (for example, COF (Chip On Film)) and hence, it is difficult to sufficiently ensure a region for arranging the cushion tape.

There has been also known a method where a liquid crystal display panel is fixed to a structural body by adhering a display screen of the liquid crystal display panel to the structural body using an adhesive double-coated tape or the like. However, the direct adhesion of the tape or the like to the liquid crystal display panel becomes a cause of the occurrence of stress in a display part. Further, it has been well-known that a liquid crystal display panel of a middle size or more is affected by heat from a backlight so that the liquid crystal display panel warps toward a display part side or a backlight side. This warping is generated due to the difference in a linear expansion coefficient or the difference in the stretching direction between an upper polarizer and a lower polarizer and hence, it is impossible to eliminate warping from a currently available liquid crystal display device. Accordingly, when the liquid crystal display panel is fixed to the structural body using the adhesive double-coated tape, the liquid crystal display panel cannot freely warp whereby stress is applied to the liquid crystal display panel thus causing display irregularities due to temperature change. The larger a size of the liquid crystal display panel, the larger an amount of warping of the liquid crystal display panel becomes and hence, the adoption of the method which fixes the liquid crystal display panel using the adhesive double-coated tape or the like becomes more difficult along with the increase of the size of the liquid crystal display panel. A high definition monitor is a product where high image quality is required in view of an intended purpose and hence, it is difficult to adopt such a method.

### SUMMARY OF THE INVENTION

It is an object of the invention to provide the protective structure of a display panel where a cushion can be mounted with favorable operability, can possess a high degree of durability, and can be mounted in a small region with a small tolerance.

(1) According to one aspect of the invention, there is provided a display device including: a display panel; a frame which holds the display panel; and a cushion which is softer than the frame, wherein the frame includes: a first portion which overlaps the display panel; a second portion which extends from the first portion more outwardly than an outer edge of the display panel; and a projecting portion which is formed on the second portion in a raised manner and faces a side surface of the outer edge of the display panel in an opposed manner, and the cushion has a hole, is mounted on the projecting portion by fitting the projecting portion in the hole, and faces the side surface of the outer edge of the display panel in an opposed manner. According to the invention, the cushion is mounted on the projecting portion by fitting the projecting portion in the hole and hence, the cushion can be mounted with favorable operability, is hardly peeled off compared to mounting of the cushion using only an adhesive material thus possessing a high degree of durability, and can be mounted in a small region with a small tolerance.

(2) In the display device described in (1), an inner peripheral surface of the hole may be brought into close contact with an outer peripheral surface of the projecting portion.

(3) In the display device described in (1), the cushion may be mounted in a state where a gap is formed between the hole and the projecting portion.

(4) In the display device described in (3), the gap may be positioned between the projecting portion and the display panel.

(5) In the display device described in any one of (1) to (4), the cushion may be mounted in a resiliently deformed state such that the cushion conforms to an outer shape of the projecting portion.

(6) In the display device described in any one of (1) to (5), the display device further may include a flexible printed circuit board which is bonded to the display panel and is pulled out from the display panel, and the cushion mounted on the projecting portion may be arranged at a position avoiding the flexible printed circuit board.

(7) In the display device described in (6), a plurality of flexible printed circuit boards may be arranged at intervals, and the cushion may be arranged between the neighboring flexible printed circuit boards.

### BRIEF DESCRIPTION OF THE DRAWINGS

FIG. 1 is a plan view of a display device according to an embodiment of the invention;

FIG. 2 is a cross-sectional view of the display device shown in FIG. 1 taken along a line II-II;

FIG. 3 is a perspective view showing the schematic mounting structure of a cushion;

FIG. 4 is a view for explaining a modification 1 of the embodiment of the invention;

FIG. 5 is a view for explaining a modification 2 of the embodiment of the invention;

FIG. 6 is a view for explaining a modification 3 of the embodiment of the invention; and

FIG. 7 is a view for explaining a modification 4 of the embodiment of the invention.

### DETAILED DESCRIPTION OF THE INVENTION

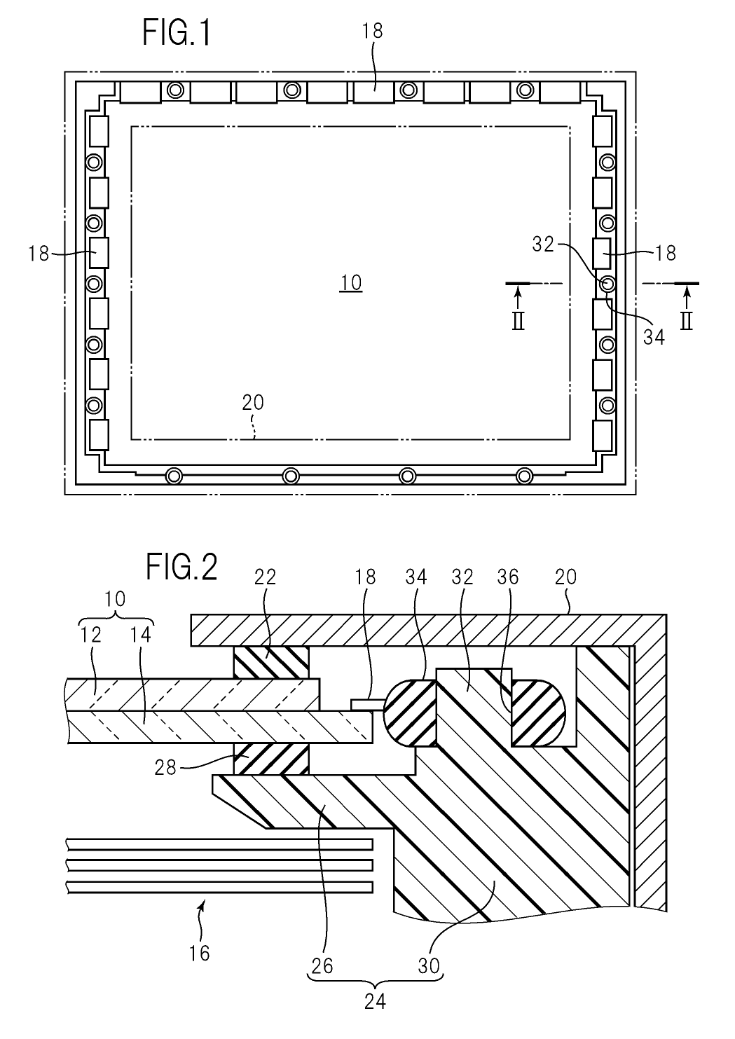

Hereinafter, an embodiment of the invention is explained in conjunction with drawings. FIG. 1 is a plan view of a display device according to the embodiment of the invention. FIG. 2 is a cross-sectional view of the display device shown in FIG. 1 taken along a line II-II.

The display device includes a display panel 10. The display panel 10 shown in FIG. 2 is a liquid crystal display panel where liquid crystal not shown in the drawing is sandwiched between a pair of substrates 12, 14 (for example, glass substrates). As shown in FIG. 2, the pair of substrates 12, 14 is arranged with end portions thereof displaced from each other such that one substrate 14 projects from the other substrate 12. Further, in FIG. 2, an optical sheet 16 which constitutes a part of a backlight of the liquid crystal display panel is shown. As the display panel 10, besides the liquid crystal display panel, an organic electroluminescence panel or the like may be used.

Flexible printed circuit boards 18 are bonded to the display panel 10 and are pulled out from the display panel 10. As shown in FIG. 1, the plurality of flexible printed circuit boards 18 are arranged at intervals. In an example shown in FIG. 1, the flexible printed circuit boards 18 are mounted on edge portions of three sides of the display panel 10 having a rectangular planar shape. However, the flexible printed circuit boards 18 may be mounted on edge portions of all four sides or may be mounted on edge portions of one side or two sides.

The flexible printed circuit board 18 has wiring (not shown in the drawing) for driving the display panel 10. When a chip part such as a semiconductor chip not shown in the drawing is mounted on the flexible printed circuit board 18, such a flexible printed circuit board 18 is referred to as a COF (Chip On Film).

The display device includes an outer frame 20 (or an upper frame). The outer frame 20 has a portion which faces an edge portion of a display screen (a surface on which an image is displayed) of the display panel 10 in an opposed manner, and the removal of the display panel 10 from the outer frame 20 is prevented by means of a resilient body 22. A gap may be formed between the resilient body 22 and the display panel 10. Although the outer frame 20 is made of metal in most cases, an impact which acts on the outer frame 20 is absorbed by the resilient body 22 and hence, the rupture of the display panel 10 can be prevented.

The display device includes a frame 24 (for example, an inner frame or an intermediate frame). The frame 24 is formed by resin molding. The frame 24 includes a first portion 26 which overlaps the display panel 10. The first portion 26 faces an edge portion of a back surface (a surface on a side opposite to the display screen) of the display panel 10 in an opposed manner, and can hold the display panel 10 by way of a resilient body 28. A gap may be formed between the resilient body 28 and the display panel 10. The resilient body 28 is made of a material softer than a material for forming the frame 24 so that an impact is absorbed by the resilient body 28 whereby the rupture of the display panel 10 can be prevented.

The frame 24 includes a second portion 30 which extends from the first portion 26 more outwardly than an outer edge of the display panel 10. The frame 24 includes a projecting portion 32 which is formed on the second portion 30 in a raised manner and faces a side surface of the outer edge of the display panel 10 in an opposed manner. The projecting portion 32 has a columnar shape, for example. In an example shown in FIG. 2, a side surface (or an outer peripheral surface) of the projecting portion 32 faces in an opposed manner at least the substrate 14 on a projecting side out of the pair of substrates 12, 14 which constitutes the display panel 10.

The display device includes a cushion 34 made of a material softer than a material for forming the frame 24. The cushion 34 is made of rubber, for example. The cushion 34 shown in FIG. 1 may be an O-ring. The cushion 34 has a hole 36.

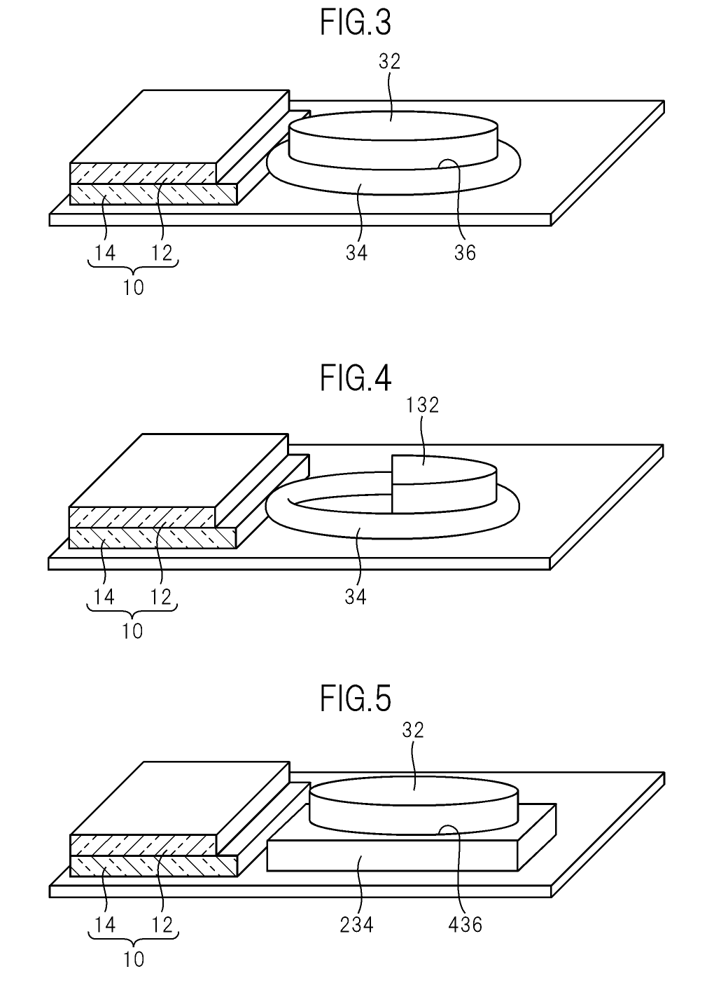

FIG. 3 is a perspective view showing the schematic mounting structure of the cushion 34. The cushion 34 is mounted on the projecting portion 32 by fitting the projecting portion 32 in the hole 36. At least a portion (for example, the whole portion) of an inner peripheral surface of the hole 36 is brought into close contact with an outer peripheral surface of the projecting portion 32. The cushion 34 faces the side surface of the outer edge of the display panel 10. In an example shown in FIG. 3, the cushion 34 faces in an opposed manner at least the substrate 14 on a projecting side out of the pair of substrates 12, 14 which constitutes the display panel 10.

As shown in FIG. 1, the cushion 34 which is mounted on the projecting portion 32 is arranged at a position avoiding the flexible printed circuit boards 18. That is, the cushion 34 is arranged between the neighboring flexible printed circuit boards 18.

According to this embodiment, the cushion 34 can be mounted on the projecting portion 32 by fitting the projecting portion 32 in the hole 36 and hence, the cushion 34 can be mounted with favorable operability, is hardly peeled off compared to mounting of the cushion 34 using only an adhesive material thus possessing a high degree of durability, and can be mounted in a small region with a small tolerance.

FIG. 4 is a view for explaining a modification 1 of the embodiment of the invention. In the modification 1, a projecting portion 132 is formed into a semi-columnar shape. Accordingly, the cushion 34 is mounted on the projecting portion 132 in a state where a gap is formed between the hole 36 and the projecting portion 132. Further, the gap is positioned between the projecting portion 132 and the display panel 10. According to this modification 1, the cushion 34 can be easily deformed due to the formation of the gap and hence, the cushion 34 can increase impact absorbing property.

FIG. 5 is a view for explaining a modification 2 of the embodiment of the invention. The modification 2 uses a cushion 234 which has a rectangular parallelepiped outer shape and in which a hole 436 is formed. Although the hole 436 has a circular shape in FIG. 5, the hole 436 may have a shape other than the circular shape such as a quadrangular shape.

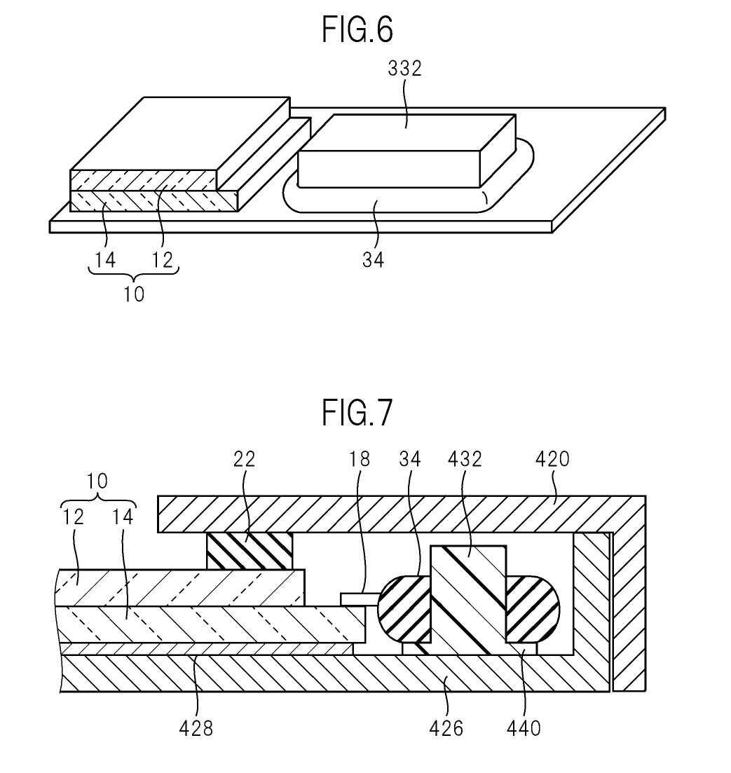

FIG. 6 is a view for explaining a modification 3 of the embodiment of the invention. In the modification 3, a cushion 34 is mounted in a resiliently deformed state such that the cushion 34 conforms to an outer shape of a projecting portion 332. To be more specific, the projecting portion 332 has a polygonal columnar shape, and the cushion 34 having a circular ring shape is deformed into a polygonal ring shape.

FIG. 7 is a view for explaining a modification 4 of the embodiment of the invention. The modification 4 is an example where the invention is applied to a liquid crystal display device having no backlight. A display panel 10 is arranged inside a lower frame 426 by way of a heat radiation material 428. A frame 440 (an inner frame or an intermediate frame) having a projecting portion 432 is also arranged inside the lower frame 426. The lower frame 426 is fixed to an upper frame 420. The projecting portion 432 may be directly formed on the lower frame 426. For example, the projecting portion 432 may be formed on the lower frame 426 by a method which directly drives a resin member or a metal member into the lower frame 426 or a method which fastens the projecting portion 432 using bolts.

The invention is not limited to the above-mentioned embodiment, and various modifications are conceivable. For example, the constitution explained in the embodiment can be replaced with the constitution which has substantially the same constitution, the constitution which acquires substantially the same manner and operation and advantageous effects or the constitution by which the same object can be achieved.

What is claimed is:

1. A display device comprising:
a display panel;
a frame which holds the display panel; and
a cushion which is softer than the frame, wherein
the frame comprises: a first portion which overlaps the display panel; a second portion which extends from the first portion more outwardly than an outer edge of the display panel; and a projecting portion which is formed on the second portion in a raised manner and faces a side surface of the outer edge of the display panel in an opposed manner, and
the cushion has a hole, is mounted on the projecting portion by fitting the projecting portion in the hole, and faces the side surface of the outer edge of the display panel in an opposed manner.

2. The display device according to claim 1, wherein an inner peripheral surface of the hole is brought into close contact with an outer peripheral surface of the projecting portion.

3. The display device according to claim 1, wherein the cushion is mounted in a state where a gap is formed between the hole and the projecting portion.

4. The display device according to claim 3, wherein the gap is positioned between the projecting portion and the display panel.

5. The display device according to claim 1, wherein the cushion is mounted in a resiliently deformed state such that the cushion conforms to an outer shape of the projecting portion.

6. The display device according to claim 1, wherein the display device further comprises a flexible printed circuit board which is bonded to the display panel and is pulled out from the display panel, and
the cushion mounted on the projecting portion is arranged at a position avoiding the flexible printed circuit board.

7. The display device according to claim 6, wherein a plurality of flexible printed circuit boards are arranged at intervals, and the cushion is arranged between the neighboring flexible printed circuit boards.
